(19) United States
(12) Patent Application Publication
(10) Pub. No.: US 2014/0339063 A1
(43) Pub. Date: Nov. 20, 2014

(54) Method And Apparatus Pertaining To A Keyboard Cover Having Light-Masking Paint

(71) Applicant: Research In Motion Limited, Waterloo (CA)

(72) Inventor: Jimmy Bedolla, Elgin, IL (US)

(73) Assignee: Research In Motion Limited, Waterloo (CA)

(21) Appl. No.: 13/896,119

(22) Filed: May 16, 2013

(51) Int. Cl. H05K 5/03; B05D 5/06

(52) U.S. Cl. CPC H05K 5/03; B05D 5/065
USPC 200/5 A; 361/679.09; 427/256

(57) ABSTRACT

A keyboard cover comprises non-opaque material and has a periphery and a plurality of key-cap receiving apertures formed therethrough to receive the various keycaps of a corresponding keyboard. By one approach the keyboard cover includes side walls disposed along the aforementioned periphery thereof, which side walls extend outwardly from the inner surface of the keyboard cover. The keyboard cover has light-masking paint disposed on only an inner surface thereof and only towards the periphery thereof By one approach the light-masking paint comprises black-colored paint. This light-masking paint can extend inwardly of the keyboard cover from the periphery thereof no further than, for example, twenty percent of the available distance. When the keyboard cover includes the aforementioned side walls, the light-masking paint can also be disposed on the inner surfaces of those side walls.

### RELATED APPLICATIONS

This application is related to co-pending and co-owned U.S. patent application No. ______ (attorney docket number 9169-130947-US (47451)), entitled method and apparatus pertaining to reversed thermoformed film and filed on even date herewith, which is incorporated by reference in its entirety herein.

This application is also related to co-pending and co-owned U.S. patent application No. ______ (attorney docket number 9169-130925-US (47452)), entitled method and apparatus pertaining to web-coupled keyboard keys and filed on even date herewith, which is incorporated by reference in its entirety herein

### FIELD OF TECHNOLOGY

The present disclosure relates generally to electronic devices and more particularly to electronic devices having back-lit keyboards.

### BACKGROUND

Electronic devices, including portable electronic devices, have gained widespread use and may provide a variety of functions including, for example, telephonic, electronic messaging and other personal information manager (PIM) application functions. Portable electronic devices include, for example, several types of mobile stations such as simple cellular telephones, smart telephones, wireless personal digital assistants (PDAs), and laptop computers and tablets/pads with wireless 802.11 or Bluetooth capabilities.

Portable electronic devices are generally intended for handheld use and ease of portability. Smaller devices are generally desirable for portability. In addition to a display (which may or may not comprise a touch-sensitive display) some portable electronic devices include a mechanical keyboard (as versus a so-called virtual keyboard) to facilitate the entry of various alphanumeric and other characters.

Many such keyboards are at least partially back-lit to facilitate use of the keyboard in a low-light or no-light situation. Light guides often serve to distribute and deliver the backlighting to the desired keycaps. Good design in these regards includes not only delivering the backlighting to desired points of illumination but also preventing light from escaping in undesired ways and thereby marring the aesthetic presentation of the backlighting effect. Unfortunately, as portable electronic devices and their keyboards grow ever smaller and thinner, achieving both proper, well-distributed and diffused backlighting and light containment grows more challenging.

### BRIEF DESCRIPTION OF THE DRAWINGS

FIG. 1 is a flow diagram in accordance with the disclosure.

FIG. 2 is a first bottom perspective view in accordance with the disclosure.

FIG. 3 is a second bottom perspective view in accordance with the disclosure.

FIG. 4 is a side-elevational schematic view in accordance with the disclosure.

FIG. 5 is a top plan view in accordance with prior art practice.

FIG. 6 is a top plan view in accordance with the disclosure.

FIG. 7 is a block diagram in accordance with the disclosure.

FIG. 8 is an elevational schematic view in accordance with the disclosure.

### DETAILED DESCRIPTION

The following describes an apparatus and method pertaining to a keyboard cover comprised of non-opaque material and having a periphery and a plurality of key-cap receiving apertures formed therethrough to receive the various keycaps of a corresponding keyboard. By one approach the keyboard cover includes side walls disposed along the aforementioned periphery thereof, which side walls extend outwardly from the inner surface of the keyboard cover. The keyboard cover has light-masking paint disposed on only an inner surface thereof and only towards the periphery thereof.

By one approach the light-masking paint comprises black-colored paint. This light-masking paint can extend inwardly of the keyboard cover from the periphery thereof no further than, for example, twenty percent of the available distance. When the keyboard cover includes the aforementioned side walls, the light-masking paint can also be disposed on the inner surfaces of those side walls.

So configured, the light-masking paint prevents light from passing through or between gaps of corresponding parts adjacent certain of the keycaps and around the keyboard cover. For example, the light-masking paint can serve to absorb light that would otherwise escape via such gaps. Such an approach, in turn, permits configuring the underside of the corresponding keyboard as a white box within which a light guide can be generally disposed to thereby facilitate delivering uniform backlighting to any or all of the keycaps.

These teachings can be economically realized and are highly effective in practice. These teachings are readily scaled as well to accommodate a variety of differently-sized keyboards, keycaps, keyboard covers, light guides, and/or portable electronic devices.

For simplicity and clarity of illustration, reference numerals may be repeated among the figures to indicate corresponding or analogous elements. Numerous details are set forth to provide an understanding of the embodiments described herein. The embodiments may be practiced without these details. In other instances, well-known methods, procedures, and components have not been described in detail to avoid obscuring the embodiments described. The description is not to be considered as limited to the scope of the embodiments described herein.

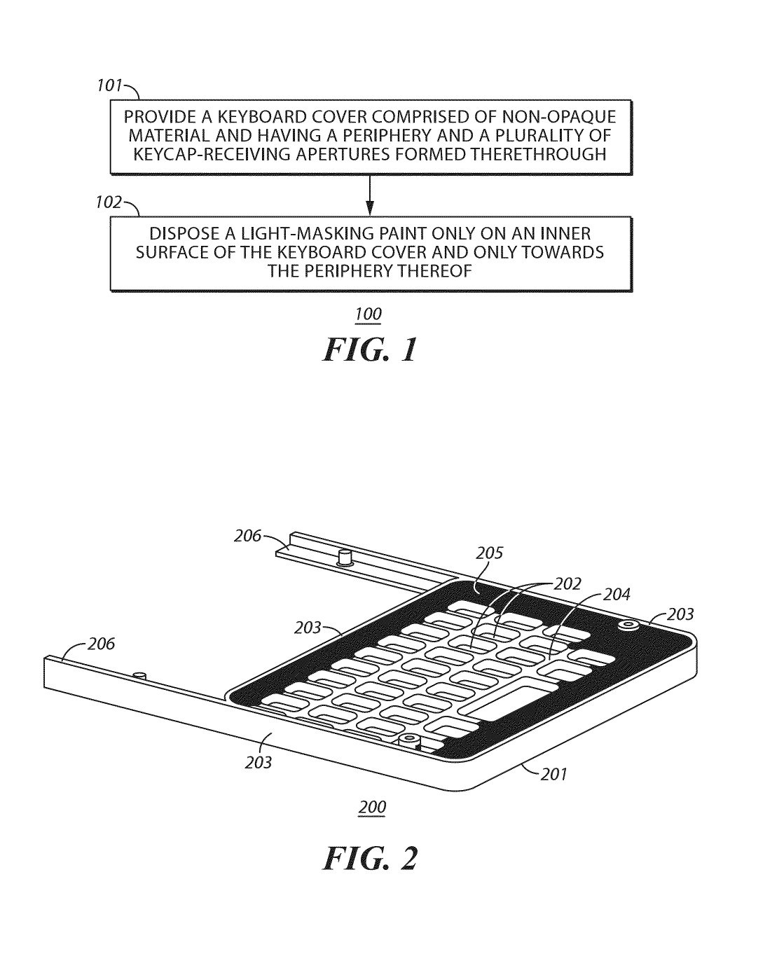

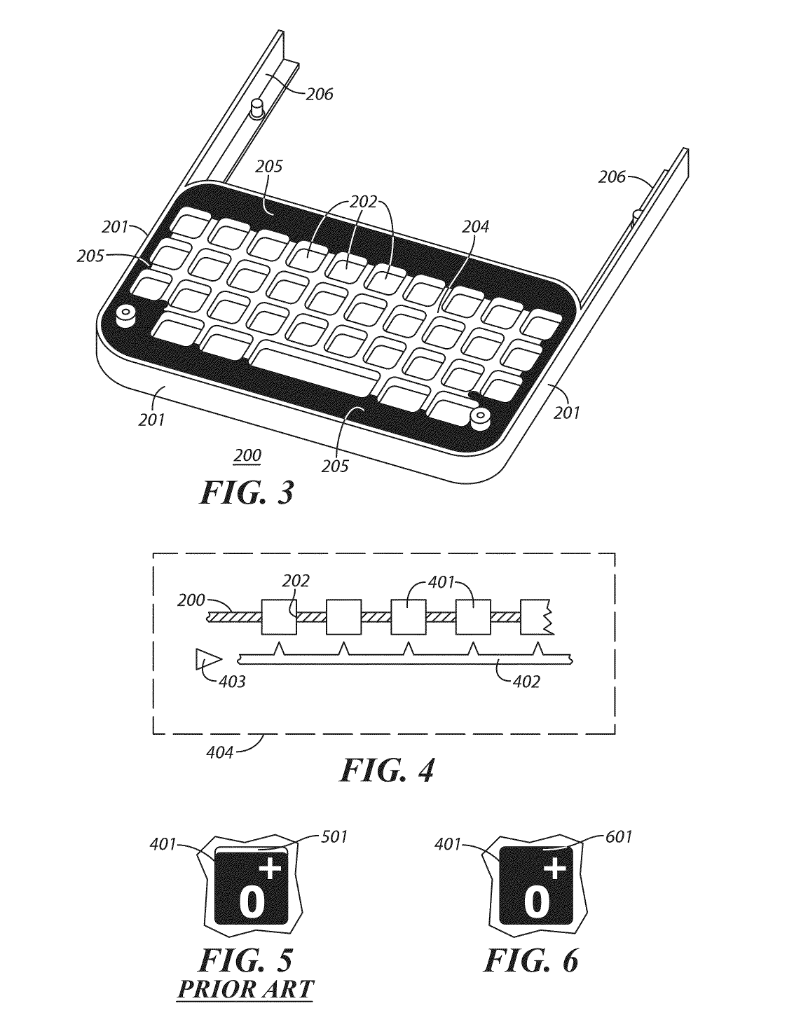

FIG. 1 presents a process 100 that comports with many of these teachings. At 101 (and referring as well to FIGS. 2 and 3) this process 100 provides a keyboard cover 200 that is comprised of a non-opaque material. By one approach this non-opaque material comprises an injection resin and the keyboard cover 200 is formed using an injection molding process. Being “non-opaque,” the material is not black in color. Examples of useful colors include gray-colored material, white-colored material, and pink/red-colored materials though these teachings can be applied in conjunction with other colors, too. (It will be understood that these teachings could, in fact, be used with a keyboard cover 200 comprised of opaque material but with little likely improvement in terms of sealing in light as the opaque material should, for most application settings, suffice in those regards.)

This keyboard cover 200 has a corresponding periphery 201 that defines the outermost physical boundary of the keyboard cover 200. In this illustrative example the periphery 201 has two rounded corners to accommodate the form factor of the portable electronic device (not shown) with which the keyboard cover 200 serves.

This keyboard cover 200 also has a plurality of keycap-receiving apertures 202 formed therethrough. In this illustrative example these keycap-receiving apertures 202 are formed into a grid having four rows. The keycap-receiving apertures 202 of the three upper rows are, in turn, formed into corresponding columns of vertically-aligned apertures. These keycap-receiving apertures 202 are sized and positioned to receive corresponding keycaps as described below.

Also in this illustrative example the keyboard cover 200 includes side walls 203 disposed along the periphery thereof. These side walls 203 extend outwardly and away from the inner surface 204 (i.e., the keyboard side of the keyboard cover 200). In this example these side walls 203 completely encircle the periphery 201 of the keyboard-containing area of the keyboard cover 200 and are of a substantially uniform depth.

It will be noted that, in this example, a pair of arms 206 extend outwardly from and coplanar with the keyboard cover 200. Though these arms 206 may be formed integral to the keyboard cover 200, it will be understood that these arms are not considered here to be a part of the keyboard cover's aforementioned periphery. Instead, as used herein, the “keyboard cover” refers to the portion that covers a keyboard and the keyboard's installation cavity when deployed and installed in conjunction with a given keyboard in a given portable electronic device.

It will be understood that the specifics shown in the illustrations are provided for the sake of an illustrative example and are not intended to represent limitations as regards these teachings. In fact, these teachings can be employed with keyboard covers having a variety of shapes and sizes, a different number and arrangement of keycap-receiving apertures, and so forth.

Referring still to FIGS. 1-3, at 102 this process 100 provides for disposing a light-masking paint 205 on some (but not all) inner surfaces of the keyboard cover 200. In particular, this light-masking paint 205 is applied only towards the periphery 201 of the inner surfaces of the keyboard cover 200. When the keyboard cover 200 includes side walls 203 as described above, this application of light-masking paint 205 includes the inner surfaces of those side walls 203.

As noted, the light-masking paint 205 is applied only towards the periphery 201 of the inner surfaces of the keyboard cover 200. By one approach, this comprises having the light-masking paint 205 reach the outer extremities of the periphery 201 and then extend inwardly from that periphery 201 no more than, say, twenty percent (of the available distance). As illustrated, in some cases the light-masking paint 205 can extend inwardly of the periphery 201 considerably less than twenty percent. For example, at the side edges of the keyboard cover 200 the light-masking paint 205 extends inwardly no more than about half-way across the width of the first keycap-receiving aperture 202.

The light-masking paint 205 will typically comprise a dark-colored paint. A black-colored paint can serve well in these regards. Generally speaking, a dull/matte finish will typically serve better for most application settings than a gloss or semi-gloss/satin finish.

By one approach the light-masking paint 205 is disposed on the keyboard cover 200 by spraying a paint solution on the inner surface 204 of the keyboard cover 200 and then allowing the paint solution to experience a chemical change to become an adhering, light-absorbing film on that inner surface 204. By another approach the paint solution is sprayed on the inner surface 204 of the keyboard cover 200 and allowed to dry to an adhering, light-absorbing film on that inner surface 204.

These teachings will accommodate using only a single application of paint or, if desired, a series of paint layer applications. If desired, these multiple paint layers can comprise different light-masking colors though for most application settings it will serve well if the final, outer paint layer comprises a black-colored layer.

In FIG. 4, such a keyboard cover 200 can be installed as a part of a corresponding keyboard 404 in a portable electronic device of choice. In particular, the keyboard cover 200 can be disposed and installed in place over the keys of a keyboard 404 such that the keycaps 401 of the keyboard 404 each extend on a one-for-one basis through a corresponding one of the aforementioned keycap-receiving apertures 202 in the keyboard cover 200. So configured, a user can selectively assert given ones of the keycaps 401 using their fingers, thumbs, or other implements of choice.

Also as shown in FIG. 4, a light guide 402 can be disposed beneath the keyboard. Light guides are generally known in the art and include, as shown here, light guides configured to work in conjunction with one or more side-firing light sources 403 (such as one or more light-emitting diodes). So configured, the light guide 402 serves to guide light from the light source(s) 403 into selected keycaps 401 and particularly towards keycap character artwork (i.e., character artwork, such as specific alphabetic characters and numbers) that is disposed on the keycaps 401.

So configured, the aforementioned light-masking paint 205 prevents light from passing through or between gaps of corresponding parts adjacent certain ones of the keycaps 401 and around the keyboard cover 200. This light masking, in turn, contributes to forming a white box underneath the keycaps 401 to thereby help form and maintain uniform back lighting underneath the keycaps 401.

FIG. 5 illustrates, at reference numeral 501, light leakage around the top edge of a given keycap 401 as can occur in the absence of the present teachings. FIG. 6 illustrates this same keycap 401 but where the light leakage is blocked at 601 by way of the light-masking paint 205 described herein.

Accordingly, so configured, a keyboard cover comprised of non-opaque material can nevertheless behave like a keyboard cover comprised of opaque material by judicious and efficacious application of light-masking paint. Such a benefit accrues at little cost.

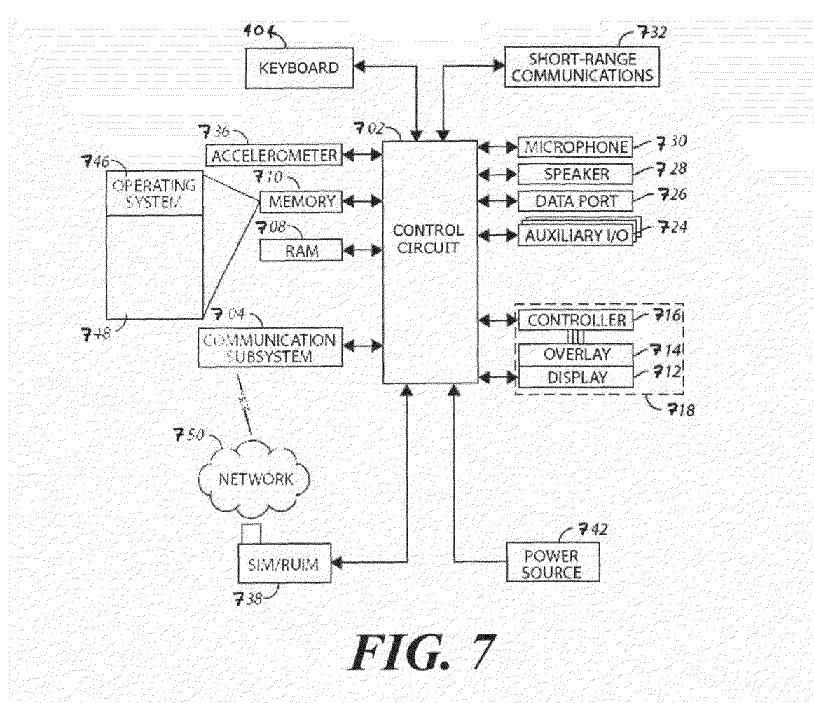

Such a keyboard 404 can serve well in a portable electronic device. Referring to FIG. 7, an exemplary portable electronic device includes a control circuit 702 that controls the overall operation of the portable electronic device. In this particular illustrative example the portable electronic device comprises a portable communications device. Corresponding communication functions, including data and voice communications, are performed through a communication subsystem 704. The communication subsystem receives messages from and sends messages to a wireless network 750.

The wireless network 750 may be any type of wireless network, including, but not limited to, a wireless data networks, a wireless voice network, or a network that supports both voice and data communications. The control circuit 702 may also operably couple to a short-range communication subsystem 732 (such as an 802.11 or 802.16-compatible transceiver and/or a Bluetooth™-compatible transceiver). To identify a subscriber for network access, the portable electronic device may utilize a Subscriber Identity Module or a Removable User Identity Module (SIM/RUIM) card 738 for communication with a network, such as the wireless network 750. Alternatively, user identification information may be programmed into a memory 710.

A power source 742, such as one or more rechargeable batteries or a port to an external power supply, powers the electronic device. The control circuit 702 may interact with an accelerometer 736 that may be utilized to detect direction of gravitational forces or gravity-induced reaction forces. The control circuit 702 also interacts with a variety of other components, such as a Random Access Memory (RAM) 708, a memory 710, an auxiliary input/output (I/O) subsystem 724, a data port 726, a speaker 728, a microphone 730, and other device subsystems 734 of choice.

A display 712 can be disposed in conjunction with a touch-sensitive overlay 714 that operably couples to an electronic controller 716. Together these components can comprise a touch-sensitive display 718 that serves as a graphical-user interface. Information, such as text, characters, symbols, images, icons, and other items may be displayed on the touch-sensitive display 718 via the control circuit 702.

The touch-sensitive display 718 may employ any of a variety of corresponding technologies including but not limited to capacitive, resistive, infrared, surface acoustic wave (SAW), strain gauge, optical imaging, dispersive signal technology, and/or acoustic pulse recognition-based touch-sensing approaches as are known in the art. If the touch-sensitive display 718 should utilize a capacitive approach, for example, the touch-sensitive overlay 714 can comprise a capacitive touch-sensitive overlay 714. In such a case the overlay 714 may be an assembly of multiple stacked layers including, for example, a substrate, a ground shield layer, a barrier layer, one or more capacitive touch sensor layers separated by a substrate or other barrier, and a cover. The capacitive touch sensor layers may comprise any suitable material, such as indium tin oxide (ITO).

One or more touches, also known as touch contacts or touch events, may be detected by the touch-sensitive display 718. The control circuit 702 may determine attributes of the touch, including a location of a touch. Touch location data may include data for an area of contact or data for a single point of contact, such as a point at or near a center of the area of contact. Generally speaking, a swipe is a touch that begins at one location on the touch-sensitive display 718 and ends at another location (as when the user places their fingertip on the touch-sensitive display 718 and then drags their fingertip along the surface of the touch-sensitive display 718 before finally lifting their fingertip from that surface).

The portable electronic device includes an operating system 746 and software programs, applications, or components 748 that are executed by the control circuit 702 and are typically stored in a persistent, updatable store such as the memory 710. Additional applications or programs may be loaded onto the portable electronic device through the wireless network 750, the auxiliary I/O subsystem 724, the data port 726, the short-range communications subsystem 732, or any other suitable subsystem 734. The memory 710 may comprise a non-transitory storage media that stores executable instructions which, when executed, causes one or more of the functions, steps, or actions described herein.

As a communication device, a received signal such as a text message, an e-mail message, or web page download is processed by the communication subsystem and input to the control circuit 702. The control circuit 702 processes the received signal for output to the display 712 and/or to the auxiliary I/O subsystem 724. A user may generate data items, for example e-mail messages, that may be transmitted over the wireless network 750 through the communication subsystem. For voice communications, the overall operation of the portable electronic device is similar. The speaker 728 outputs audible information converted from electrical signals, and the microphone 730 converts audible information into electrical signals for processing.

The control circuit 702 further operably couples in this illustrative example to the aforementioned keyboard 404. This keyboard 404 can comprise, for example, a QWERTY keyboard that includes a complete set of alphabetic characters along with various numerals, grammatical symbols, and so forth as desired.

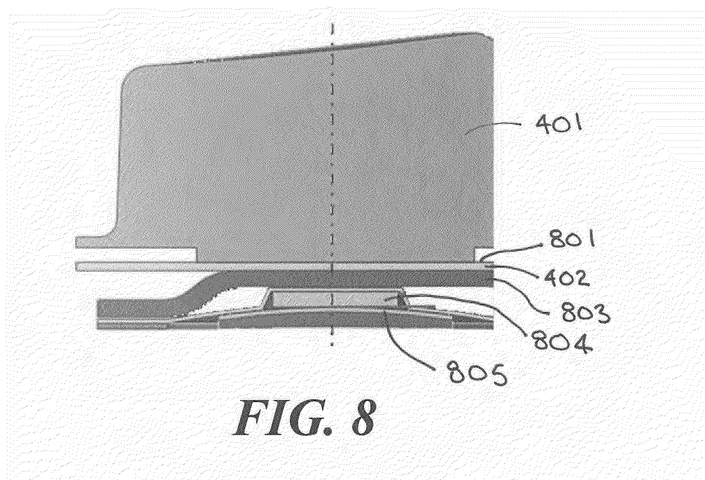

FIG. 8 provides some further illustrative details as regards one approach to the individual keys of such a keyboard 404. In this example each keycap 401 is atop a thermoplastic polyurethane layer 801 that is, by way of example, 0.18 millimeters thick and having a black-colored topside and a matte white-colored bottom side. Next is a thermoplastic polyurethane light guide film 402 having a thickness of about 0.2 millimeters followed by a dome sheet 803, an actuator 804, and a dome switch having a collective height of about 0.493 millimeters. So configured, pressure exerted by a user upon the keycap 401 will urge the latter towards the actuator 804. The actuator 804 in turn will then contact the dome switch 805 and cause the latter to close (hence sensing and marking the user's assertion of a particular keycap 401).

The present disclosure may be embodied in other specific forms without departing from its essential characteristics. The described embodiments are to be considered in all respects only as illustrative and not restrictive. The scope of the disclosure is, therefore, indicated by the appended claims rather than by the foregoing description. All changes that come within the meaning and range of equivalency of the claims are to be embraced within their scope.

1. An apparatus comprising:
a keyboard cover comprised of non-opaque material and having a periphery and a plurality of keycap-receiving apertures formed therethrough, the keyboard cover having light-masking paint disposed only on an inner surface thereof and only towards the periphery thereof.

2. The apparatus of claim 1 wherein the non-opaque material comprises an injection resin.

3. The apparatus of claim 1 wherein the non-opaque material comprises a gray-colored material.

4. The apparatus of claim 1 wherein the keycap-receiving apertures include a plurality of keycap-receiving apertures that are arranged in parallel columns and rows.

5. The apparatus of claim 1 wherein the light-masking paint extends inwardly of the keyboard cover from the periphery thereof no more than twenty percent.

6. The apparatus of claim 1 wherein the light-masking paint comprises black paint.

7. The apparatus of claim 1 wherein the keyboard cover includes side walls disposed along the periphery thereof and extending outwardly from the inner surface.

8. The apparatus of claim 1 wherein the inner surface of the keyboard cover that has the light-masking paint disposed thereon includes inner surfaces of the side walls.

9. The apparatus of claim 1 further comprising:
a keyboard comprising a plurality of keycaps that are each disposed on a one-for-one basis through a corresponding one of the keycap-receiving apertures.

10. The apparatus of claim 9 further comprising:
a light guide disposed beneath the keyboard and configured to guide light into keycap character artwork while maintaining uniform back lighting to all of the keycaps, wherein the light-masking paint prevents light from passing through or between gaps of corresponding parts adjacent the keycaps and around the keyboard cover.

11. The apparatus of claim 10 wherein the apparatus further comprises:
a portable electronic device having a user interface that includes the keyboard cover, keyboard, and light guide.

12. A method comprising:
providing a keyboard cover comprised of non-opaque material and having a periphery and a plurality of keycap-receiving apertures formed therethrough;
disposing a light-masking paint only on an inner surface of the keyboard cover and only towards the periphery thereof.

13. The method of claim 12 wherein providing the keyboard cover comprises injection molding the keyboard cover.

14. The method of claim 12 wherein
providing the keyboard cover comprises providing a keyboard cover having side walls disposed along the periphery thereof and extending outwardly from the inner surface; and
disposing a light-masking paint only on an inner surface of the keyboard cover and only towards the periphery thereof includes disposing the light-masking paint on inner surfaces of the side walls.

15. The method of claim 14 wherein disposing a light-masking paint only on an inner surface of the keyboard cover and only towards the periphery comprises disposing the light-masking paint about a full extent of the periphery.

16. The method of claim 15 wherein disposing a light-masking paint includes spraying a paint solution on the inner surface of the keyboard cover and allowing the paint solution to dry to an adhering, light-absorbing film on the inner surface.

17. The method of claim 15 wherein disposing a light-masking paint includes spraying a paint solution on the inner surface of the keyboard cover and allowing the paint solution to experience a chemical change to an adhering, light-absorbing film on the inner surface.

18. An apparatus comprising:
a keyboard cover comprised of non-opaque injection-molded material and having:
a periphery and side walls disposed along the periphery and extending outwardly from an inner surface of the keyboard cover;
a plurality of keycap-receiving apertures formed through the keyboard cover in, at least in part, a grid-like pattern; and
light-masking paint disposed only on inner surfaces thereof and only towards the periphery.

19. (canceled)
